(19) United States
(12) Patent Application Publication
(10) Pub. No.: US 2002/0066179 A1
(43) Pub. Date: Jun. 6, 2002

(54) System and method for metalization of deep vias

(76) Inventors: Hendley W. Hall, San Pedro, CA (US); Wayne K. Finn, Torrance, CA (US)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/727,650

(22) Filed: Dec. 1, 2000

(51) Int. Cl. H05K 3/10; B05C 13/02

(52) U.S. Cl. 29/852; 29/846; 118/44; 118/500

(57) ABSTRACT

In a method of injecting an electrically conductive epoxy into blind vias during drilling or shortly thereafter in order to avoid oxidation of the copper or other metal of the imbedded layer, a machine tool is provided with at least one controllable spindle and at least one injection device. Alternatively, two machine tools, one with at least one controllable spindle and one with at least one injection device, may be provided. A printed circuit board mounted on the machine tool table for drilling is registered in the usual way for the particular machine tool. The machine tool part program then drills a particular pattern for the circuit board for mounting of circuit board components. All of the blind vias as well as through hole vias are drilled at one time by the machine tool by the tools mounted in the spindle or by laser drilling systems, but may also be drilled and filled in any sequence. The drilling operation is followed by the epoxy injecting operation in which a controlled operating device, comprising a reservoir, a pumping mechanism, a hollow needle through which the conductive epoxy flows to the bottom of the hole, a control mechanism, and sensors detect various mechanism operations and when hole fill is completed.

### BACKGROUND OF THE INVENTION

1. Field of the Invention

The field of this invention relates generally to drilling and metalization of printed circuit boards. More particularly, the field of this invention relates to enhanced metalization of deep vias.

2. Related Art

Machine tools have been used to drill holes through printed circuit boards for many years. Subsequent to the drilling of such holes, interhole plating or metalizing is required to ensure appropriate electrical connection. Such metalization systems include the electrical explosive techniques, and other generally-known metalization methods. Often, such circuit boards are multilayered, which require holes to be drilled to a layer within the circuit board instead of through the board. These holes are called blind vias because they terminate at one end.

Plating differs from through holes in that the blind vias are limited in depth, generally, to an aspect ratio of 1 to 1.2, in order to ensure that adequate plating can take place. A system of channel plating using a conductive epoxy has been used which permits the plating of a channel routed in a surface to be plated with an electrically conductive adhesive which is later followed by a squeegee which forces the conductive epoxy into the channel in one pass of the squeegee. However, where blind vias are to be plated, and in particular, deep blind vias having aspect ratios of greater than 1.2, use of the squeegee method causes bubbles to be formed at the bottom of the blind via thereby preventing sufficient electrical contact and sometimes any contact at all with the imbedded layer.

Because present technology and practices do not allow high aspect ratio blind vias to be adequately metalized or plated, many added circuits are threaded throughout the multilayer circuit boards to bring discreet circuits near an outside surface of the board so that current low aspect ratio holes can make the connections necessary between circuits.

Other methods include changing the shape of the pins of the circuit board components which are inserted into the holes such that the pins themselves force out or collapse the bubbles.

However, the method is not a positive one in that bubbles are nevertheless formed and while the pin modification may be able to correct this bubble formation, it does not prevent it. In addition, special circuit board components are fabricated to implement this correction problem and make the components more expensive, in addition to requiring increased inventory to carry both conductive epoxy components and standard fabrication components.

While the air bubble is one problem that prevents the fluid epoxy from completely filling the hole, there are other problems. For one, there is the inability to completely remove fluid from the deep vias. In the plating process, the circuit boards go through a number of acid and rinse baths and if there is any fluid retained in the hole by surface tension or capillary action, such fluid may damage the solution used the next one, two or three or more baths and prevent adequate plating. Another problem is the inability to replace the depleted fluid in a deep hole. The plating process requires the material that is to be deposited to be in the solution of the bath. A small hole has a very small amount of fluid in which plating or metalizing material is in suspension and when such material is depleted, the exhausted fluid must be re-circulated to get more material-laden fluid into the hole to continue the plating process. If new fluid is not able to replace the exhausted fluid in the hole, the plating in the hole will be to thin to adequately act as a current carrier. A further problem is that holes may blind over or seal themselves with plating material at the top before the bottom or sides of the hole are plated. This sealing action occurs because the fluid outside the hole has good circulation and is saturated with plating material which causes the plating at the surface of the hole to occur more rapidly than the plating at the bottom of the hole. Thus, the plating process can cover over the hole before the plating down inside the hole is thick enough to be of any electrical value.

A method of ensuring that bubbles are not formed and which permits the metalization of deep blind vias is required. The present invention provides a method and a system which allows for metalization of deep vias without bubble formation.

### SUMMARY OF THE INVENTION

The present invention is a system and method of injecting an electrically conductive epoxy into blind vias during drilling, or shortly thereafter, in order to avoid oxidation of the copper or other metal of the imbedded layer. In a first preferred implementation, the machine tool is provided with at least one controllable spindle and at least one injection device. In a second preferred implementation, at least one injection device is provided on a separate machine tool from a machine tool having at least one controllable spindle.

In the case of the first preferred implementation, the printed circuit board that is mounted on the machine tool worktable for drilling is registered in the usual way for the particular machine tool. The machine tool part program then drills a particular pattern for the circuit board for mounting of circuit board components. All of the blind vias as well as through hole vias are drilled at one time by the machine tool by the tools mounted in the spindle or by laser drilling systems. The drilling operation is followed by an epoxy injecting operation by a controlled operating device comprising a reservoir, a pumping mechanism, a hollow needle through which the conductive epoxy flows to the bottom of the hole, a control mechanism, and sensors to detect various mechanism operations.

The hollow needle is inserted into each of the holes to the depth drilled and filled with conductive epoxy, in sequence, until all holes are filled.

This is advantageous in that the PCB being worked remains in the registration position and the system knows the precise location of each of the drilled holes and their characteristics including, in particular, their depth.

While it is preferred that all of the holes be drilled first followed by the injection of conductive epoxy, the epoxy injector may follow the drill and fill the holes immediately after the drilling by the spindle or laser, provided the spindle or laser head have moved to new drilling positions away from the drilled hole a sufficient distance to permit the injector to be moved to the hole to be plated.

In the case of the second preferred implementation, the drilled printed circuit board is removed the machine tool for drilling and remounted and reregistered for the epoxy injecting operation. Here, care must be taken to ensure that the delay between drilling and injection of conductive epoxy does not cause oxidation or corrosion of the copper or other conductive layer imbedded in the circuit board thereby degrading plating.

In either case, since the blind vias are injected by needle, the tip thereof is positioned at the bottom of the via regardless of depth, and thus eliminates the bubble which is pushed away from the bottom by the injected epoxy.

Various kinds of needles can be used which either fills the blind via completely, or merely coats the sides thereof for receipt of printed circuit board components, either immediately after drilling and plating or at a subsequent insertion point.

The present invention allows for high aspect ratio blind vias to reach deep within the printed circuit board, eliminating the need for much of the threading of circuits up through the multilayer. This lessens the complication of the inner layers and provides more real estate for other uses and functions.

### BRIEF DESCRIPTION OF THE DRAWINGS

FIG. 1 is a perspective view of a machine tool having a worktable with a plurality of spindles and epoxy injectors.

FIG. 2 is a side view of a blind via with a bubble at the bottom thereof.

FIG. 3 is a view of a spindle drilling a hole and an injector positioned in a previously drilled hole for injecting conductive epoxy in said hole.

FIG. 4 is a view of a laser beam directed to the workpiece for drilling a hole and an injector positioned in a previously laser-drilled hole for injecting conductive epoxy in said hole.

FIGS. 5A-5C are side views of the needle in a blind via injecting conductive epoxy to fill the blind via to a selected layer.

FIGS. 6A-6D are side views of the needle in a blind via injecting conductive epoxy for coating the blind via.

FIGS. 7A-7E is a flow diagram of the method of forming, filling and coating blind vias.

### DESCRIPTION OF THE SPECIFIC EMBODIMENTS

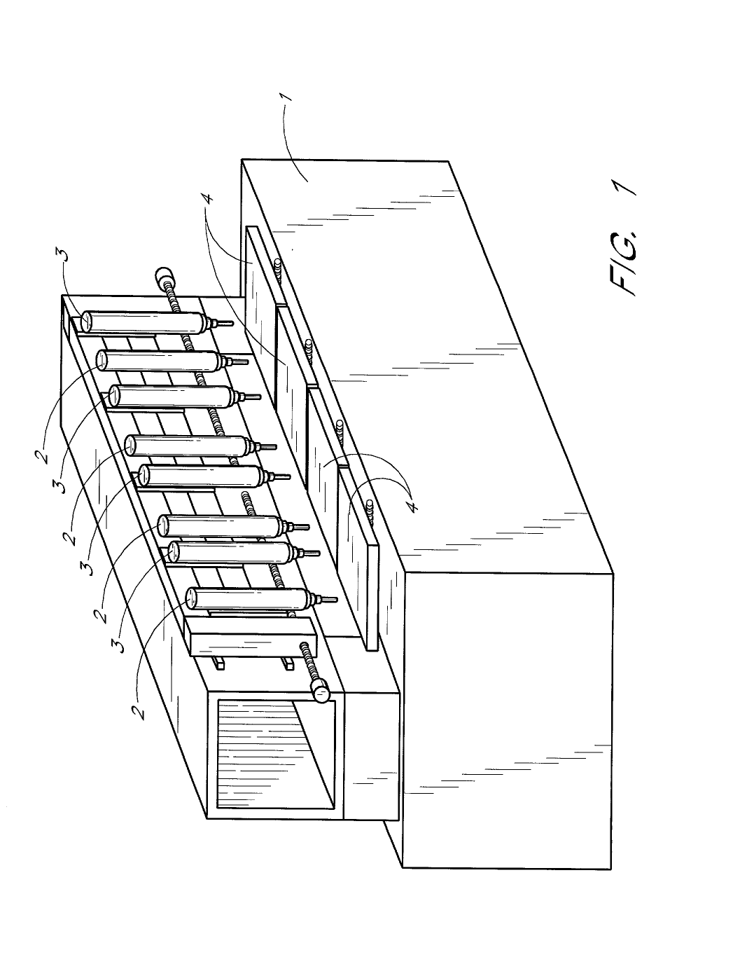

Referring now to the drawings, FIG. 1 shows a typical machine tool which has a plurality of spindles 2 having tools 2a mounted thereon. Individual ones of said spindles are positioned over each of a plurality of worktables 4. Each of the spindles 2 is accompanied by an epoxy injector 3 which comprises a hollow injector needle 3a and an epoxy reservoir 3b for carrying a supply of conductive epoxy 5. The needle may have holes in the sides thereof as well. A compression system not shown applies pressure through a hose 3c and fitting 3d to the epoxy reservoir 3b to force measured amounts of conductive epoxy through the needle and into a workpiece mounted on the worktable 4. The diameter of the hollow injector needle 3a is equal to or smaller than the diameter of the drilled hole.

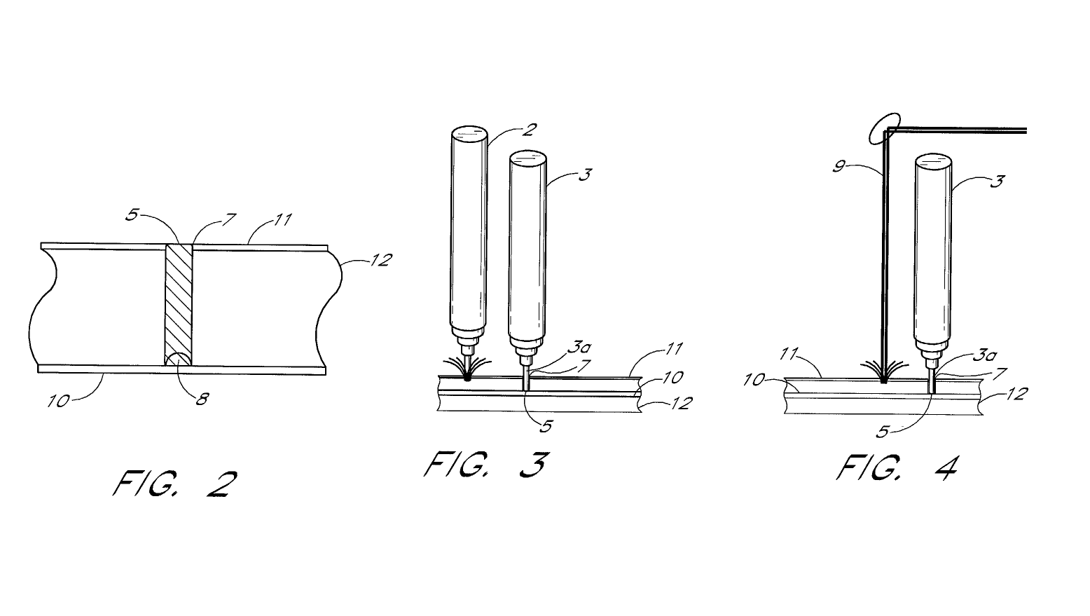

Referring now to FIG. 2, the prior art method of filling routed channels is not satisfactory for filling holes 7 in a PCB 12 with electrically conductive epoxy 5 because using the squeegee method results in the creation of a bubble of air 8 at the bottom of the hole 7.

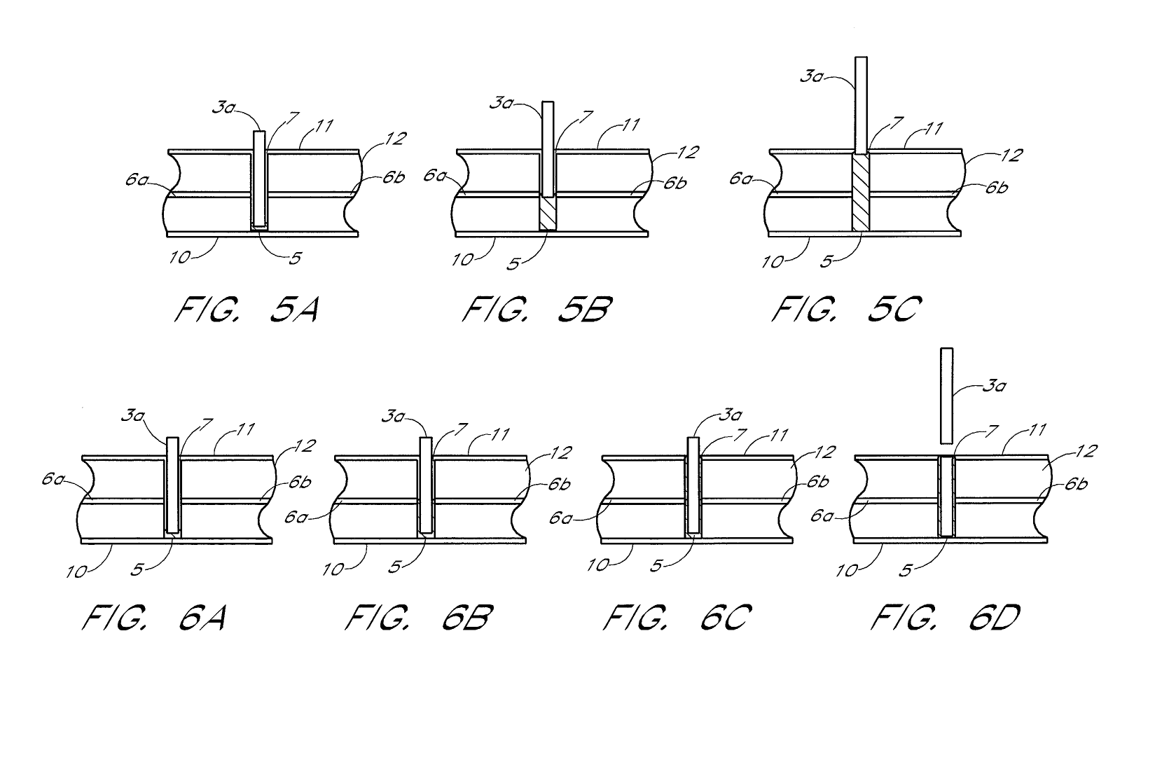

FIG. 3 shows the spindle 2 drilling a hole 7 into a PCB 12 surface while the injector 3 has positioned the needle 3a to the bottom of a previously drilled hole 7 for injection of the electrically conductive epoxy 5. FIG. 4 shows a laser beam 9 drilling a hole 7 in the PCB 12 surface while the injector 3 has positioned the needle 3a to the bottom of a previously drilled hole 7 for injection of the electrically conductive epoxy 5. For the purposes of the present invention, it does not matter what operative apparatus drills the holes, as the injection apparatus of the present invention may be used to inject conductive epoxy or any other conductive material into any hole.

FIG. 5A shows the needle 3a positioned near the bottom of the hole 7 and the commencement of injection of the conductive epoxy 5 at the bottom of the hole 7 onto a conductive layer 10. The needle 3a is moved out of the hole 7 as the injection of conductive epoxy 5 continues as shown in FIG. 5B. FIG. 5B also shows an inner layer 6 which is electrically connected to layer 10 by the electrically conductive epoxy 5. If inner layer 6 and layer 10 are to be so connected, the injection of conductive epoxy may be terminated prior to reaching surface layer 11. If the particular blind via represents a common connection ground, then the injection may be continued until layer 11 is also electrically connected. In either case, the creation and plating of the blind via may be used to selectively interconnect inner or intermediate layers. Finally, as shown in FIG. 5C, the needle 3a is entirely removed from the hole 7 and injection of conductive epoxy 5 terminates as the hole 7 is completely filled. This ensures electrical conductivity between the layer 10 at the bottom of the hole 7 and the layer 11 at the surface of the PCB, and any intermediate layer in between.

In the event that electrical conductivity between layers 10 and 11 is to be ensured with a later insertion of pins (or leads) of electrical components, a thin layer of conductive epoxy may be applied to the inner surface of the holes, which due to the small diameter thereof will adhere to the walls due to surface friction of the inner walls. The needle 3a must be smaller than the hole and approximate the size of the hole desired after plating. The needle is positioned at the bottom of the hole as before and, as shown in FIG. 6A, injection is begun. In this case, the conductive epoxy will be forced up the walls of the hole and adhere to the sides thereof, as shown in FIG. 6B. When the level of the conductive epoxy reaches the surface of the PCB, it maybe detected by conventional means and the injection of conductive epoxy terminated, as shown in FIG. 6C. The needle 3a is then withdrawn, as shown in FIG. 6D, leaving a metalized deep via ready to receive a component pin and additional conductive epoxy at a later time. Care must be taken when coating a deep via because a vacuum may be created as the needle 3a is withdrawn, which may suck the conductive epoxy off the walls or otherwise displace the coating. Some experimentation may be required to adjust the epoxy viscosity and the rate of removal of the hollow needle. The type of needle used is also important. The needle may be a simple hollow needle with an open end, a hollow needle with a closed end and one or more openings in the sides thereof, or a hollow needle having both an open end and one or more openings in the sides thereof. Some experimentation with the selection of the needle to be used will also be required for a proper coating action. One the coating is applied, the pins of a printed circuit package may be inserted at any later time using a small amount of additional electrically conductive epoxy applied to the pins and inserted into the plated via without concern for proper conduction being established between the layer 11 and the layer 10 or, as the case may be, layer 6.

The needle 3a may be coated with TEFLON® or any suitable a release material to facilitate removal of the needle 3a.

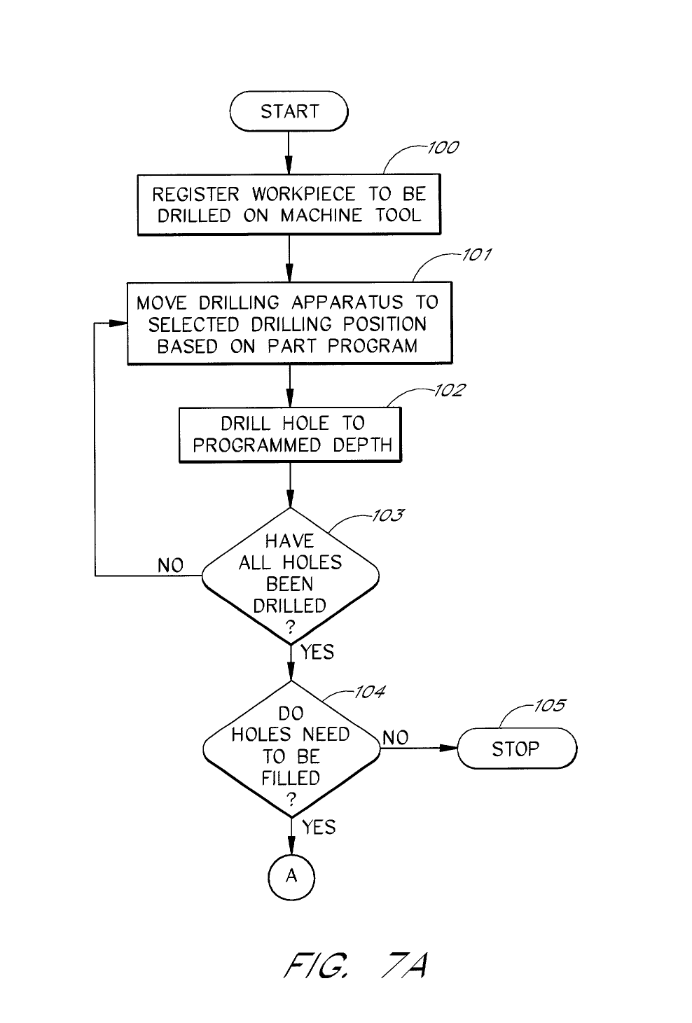

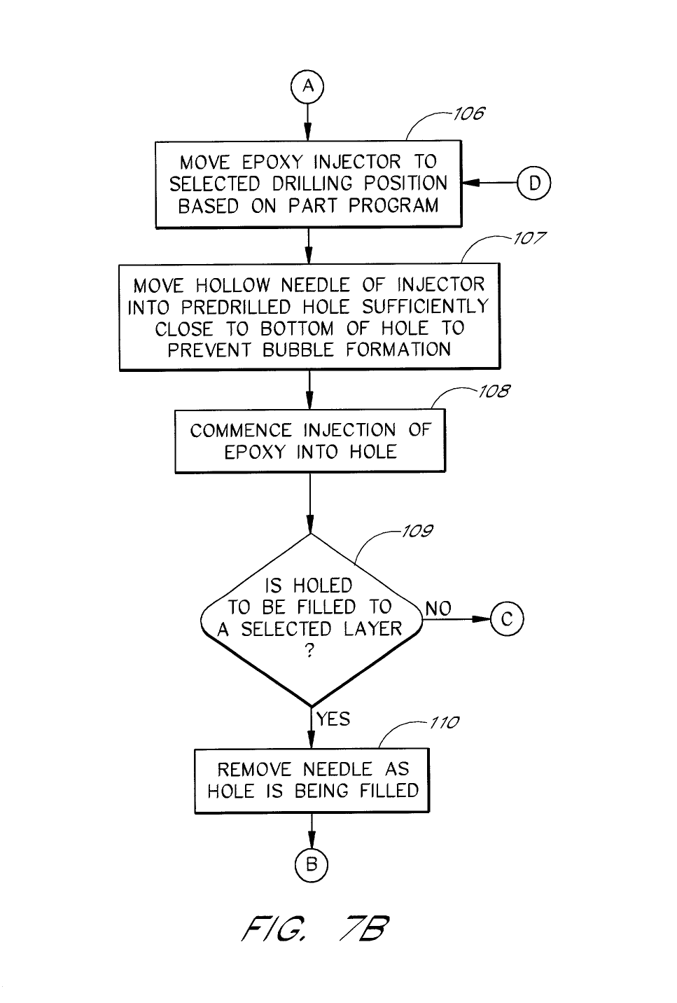

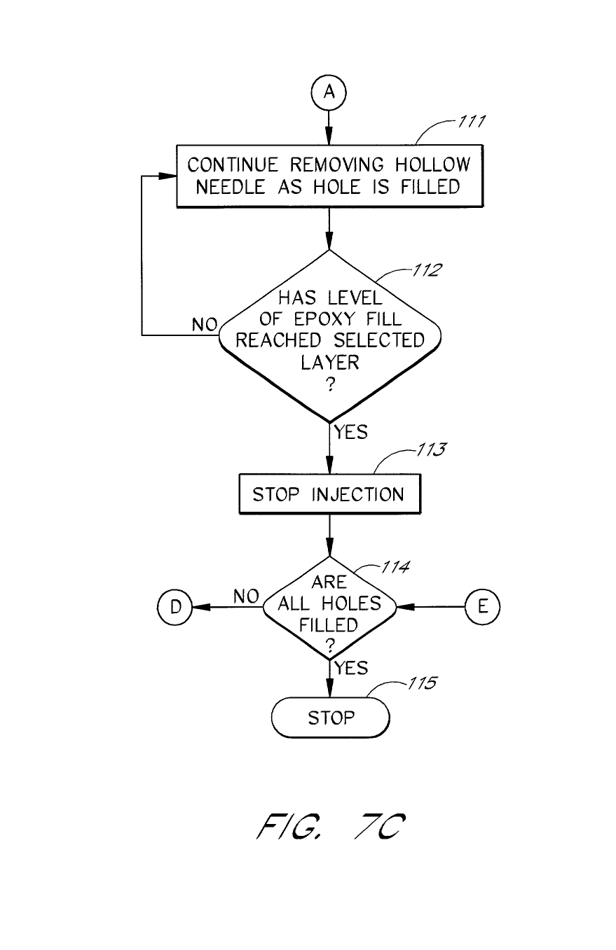

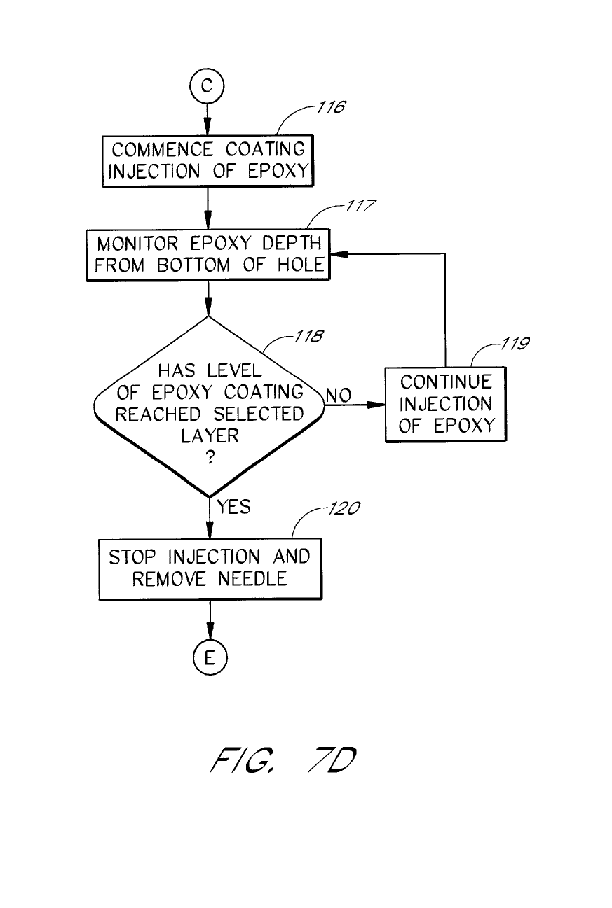

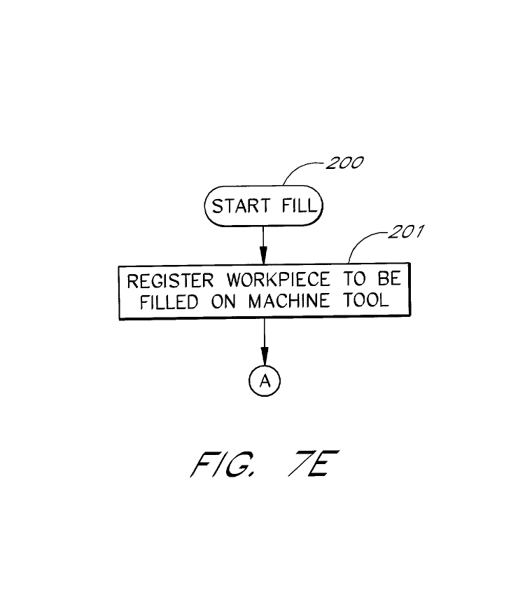

During operation, referring to FIGS. 7A through 7D, the workpiece or PCB is registered on the worktable in the conventional manner, step 100. A part program is loaded or has been previously loaded into the machine tool 1 computer and drilling commences based on the part program which defines the location and depth of the holes 7 to be drilled into the workpiece. The drilling apparatus or the worktable or both are moved to position the drilling apparatus to the selected drilling position, step 101.

The hole 7 is then drilled to the programmed depth, step 102. If the holes 7 have not all been drilled in accordance with the part program, step 103, then the drilling apparatus is moved to the next selected position, step 101, and the drilling is again performed. When all of the holes 7 have been drilled, step 103, and the holes 7 are to be filled with conductive epoxy 5, step 104, the conductive epoxy injector 3 is moved to the selected drilling position based on the part program, step 106. This is an advantage because the workpiece 4 was registered initially for drilling and the system therefore can determine precisely where the blind vias and through holes are positioned, as well as the depth of each of the drilled holes 7. The hollow needle 3a of the injector 3 is positioned at the bottom of the hole 7 and spaced apart a sufficient distance to permit flow of conductive epoxy 5 in the hole 7 and force out air to avoid air pockets 6, step 107. The injection of conductive epoxy 5 then commences, step 108.

If the hole 7 is to be entirely filled, step 109, the needle 3a is gradually removed as the conductive epoxy 5 is injected to ensure the hole 7 is entirely filled, step 110. The rate at which the needle 3a is retracted from the hole 7 is dependent on the volume of the hole 7 and the rate at which the conductive epoxy 5 is injected. The needle 3a continues to be removed as the conductive epoxy 5 is injected, step 111. When the needle 3a reaches the surface of the PCB, step 112, the injection of conductive epoxy 5 is terminated, step 113. If all of the holes 7 have been filled, step 114, the process terminates, step 115. If holes 7 remain to be filled, step 104, the epoxy injector 3 is moved to the next drilling position as determined by the part program, step 106, and the process continues until all holes 7 are filled.

Optionally, if the holes 7 are not to be filled, step 109, then they are to be coated with electrically conductive epoxy 5. The needle 3a which is smaller in diameter than the hole 7, and is already positioned at the bottom of the hole 7 commences injection of the conductive epoxy 5 in the hole 7, step 116. In this case, the conductive epoxy 5 will flow up around the needle 3a which remains in position at the bottom of the hole 7. The level of conductive epoxy 5 is monitored to determine when the conductive epoxy 5 in the hole 7 reaches the surface of the PCB 12, step 118.

If the conductive epoxy 5 has not reached the surface of the PCB 12, step 118, then injection continues, step 119, and the level of the conductive epoxy 5 is continuously monitored. If the conductive epoxy 5 reaches the surface, step 118, injection is terminated and the needle removed, step 120.

The system then checks to see if all holes 7 have been completed, step 114, and if not, the process continues, step 106. If all holes 7 are coated, then the process stops, step 115.

If the workpiece or PCB 12 has been removed from the worktable 4 after drilling, the present invention may still be utilized except that the workpiece must be re-registered on the worktable 4. It is best to perform the injection operation immediately after drilling to ensure that debris 10 does not enter the vias and corrosion of the exposed layer surfaces does not occur. In particular, this is advantageous where the number of holes 7 to be injected with conductive epoxy 5 is high relative to the number of holes 7 drilled, and time lost due to a need to re-register the workpiece and load the correct part program is avoided. However, if the number of holes 7 to be injected with conductive epoxy 5 is low relative to the number holes drilled in the workpiece, it may be more efficient to perform a separate injecting operation, using a separate machine tool for injecting conductive epoxy 5 only. Of course, this separate injecting operation can also be performed on a machine tool having both the spindle 2 and epoxy injector 3.

Referring to FIG. 6E, the fill operation, step 200, commences with the registration of the workpiece to be filled on the machine tool, step 201, and the epoxy injector 3 is moved to a selected drilling position based on the part program, step 106, and the process commences anew. Finally, while the invention has been described as first drilling all of the holes in the workpiece and then plating all of the holes in the workpiece thereafter, due to the independent control of the drilling spindle or the laser drilling apparatus and the epoxy injector, the filling of holes may be commenced before the drilling of the hole patterns have been completed. Care should be taken to ensure that the movement of the spindle or the laser mirrors, as the case may be, and the epoxy injector do not interfere with one another due to the size of the operative apparatus. Accordingly, a safe distance between the hole drilled and the holes filled or coated should be maintained to prevent collision of the devices. Once this is accomplished, operation of the drilling and plating functions can occur concurrently providing an additional time savings.

While a specific embodiment of this invention has been described above, those skilled in the art will readily appreciate that many modifications are possible in the specific embodiment, without materially departing from the novel teachings and advantages of this invention. Accordingly, all such modifications are intended to be included within the scope of this invention, as defined in the following claims.

Having thus described the invention, what is claimed is:

1. A machine tool for metalizing a plurality of vias in at least one printed circuit board comprising:
a) a worktable upon which said at least one printed circuit board is mounted; and
b) at least one injection apparatus mounted on said machine tool for injecting a conductive material into at least one of the vias of said at least one printed circuit board.

2. A machine tool as described in claim 1, wherein one or both of said worktable and said at least one injection apparatus is moveable such that said at least one injection apparatus can be positioned appropriately to inject said conductive material into at least one of the vias of said at least one printed circuit board.

3. A machine tool as described in claim 1, wherein relative movement between said worktable upon and said injection apparatus positions selected vias of said plurality of vias for injection of said conductive material for metalization of said selected vias.

4. A machine tool as described in claim 1, further comprising means for applying relative movement between said moveable worktable and said injection apparatus to position a selected via of said plurality of vias at said injection apparatus for injection of said conductive material into said selected via.

5. A machine tool as described in claim 1, further comprising a drilling apparatus for forming said at one deep via in said printed circuit boards.

6. A machine tool as described in claim 4, wherein relative movement between said worktable upon which said printed circuit boards are mounted and said injection apparatus positions said at least one deep via at said injection apparatus for injection of said conductive material into said deep via.

7. A machine tool as described in claim 1, wherein said injection apparatus further comprises a hollow needle which has an outside diameter smaller than the diameter of said via.

8. A machine tool as described in claim 1, wherein said conductive material is an electrically conductive epoxy.

9. A method of metalizing vias between conductive layers comprising:
a) positioning an injection apparatus at a selected via;
b) moving said injection apparatus into said selected via;
c) injecting a conductive material into said selected via; and
d) removing said injection apparatus from said selected via.

10. A method of metalizing vias as described in claim 9, wherein the step d) of removing said injection apparatus is performed simultaneously with the step c) of injecting a conductive material into said selected via.

11. A method of metalizing vias as described in claim 10, further comprising:
a) monitoring the conductive material being injected into said selected via until the level of conductive material reaches a selected conductive layer; and
b) terminating the injection of conductive material when the level of conductive material reaches a selected conductive layer.

12. A method of metalizing vias as described in claim 9, wherein removing said injection apparatus from said via is performed after conductive epoxy is injected.

13. A method of metalizing as described in claim 12, further comprising:
a) monitoring the conductive material being injected into said selected via until the level of conductive material reaches a selected conductive layer; and
b) terminating the injection of conductive material when the level of conductive material reaches a selected conductive layer.

14. A method of drilling and metalizing at least one deep via in at least one printed circuit board comprising:
a) drilling said at least one via in said printed circuit board with a drilling apparatus to a selected depth;
b) moving the drilling apparatus away from said at least one via;
c) positioning an injection apparatus at said via;
d) moving said injection apparatus into said via to a selected depth;
e) injecting a conductive material into said via; and
f) removing said injection apparatus from said via.

15. A method of drilling and metalizing at least one deep via as described in claim 14, further comprising:
a) moving said drilling apparatus to another selected deep via drilling position;
b) drilling said another selected deep via in said printed circuit board with said drilling apparatus to said selected depth;
c) moving the drilling apparatus away from said another selected deep via;
d) positioning an injection apparatus at said another selected deep via;
e) moving said injection apparatus into said another selected deep via;
f) injecting a conductive material into said another selected deep via; and
g) removing said injection apparatus from said another selected deep via.

16. A method of drilling and metalizing deep vias as described in claim 15, wherein the step g) of removing said injection apparatus from said another selected via is performed simultaneous with the step f) of injecting a conductive material into said selected deep via.

17. A method of drilling and metalizing deep vias as described in claim 16, further comprising:
a) monitoring the conductive material being injected into said selected via until the level of conductive material reaches a selected conductive layer; and
b) terminating the injection of conductive material when the level of conductive material reaches a selected conductive layer.

18. A method of drilling and metalizing deep vias as described in claim 15, wherein the step g) of removing said injection apparatus from said another selected via is performed after the step f) of injecting a conductive material into said selected deep via.

19. A method of drilling and metalizing deep vias as described in claim 18, further comprising:
a) monitoring the conductive material being injected into said selected via until the level of conductive material reaches a selected conductive layer; and
b) terminating the injection of conductive material when the level of conductive material reaches a selected conductive layer.

20. A method of drilling and metalizing a plurality of deep vias in at least one printed circuit board comprising:
a) positioning a drilling apparatus at a selected position;
b) drilling a deep via with a drilling apparatus at a selected position to a predetermined depth so that the aspect ratio is greater than 1.2;
c) moving the drilling apparatus away from said deep via drilled at said selected position;
d) positioning an injection apparatus at said drilled deep via;
e) moving said injection apparatus into said drilled deep via to a selected depth;
f) injecting a conductive material into said drilled deep via;
g) removing said injection apparatus from said drilled deep via;
h) selecting another drilling position;
i) drilling another deep via at another selected drilling position to said predetermined depth; and
j) repeating the steps a) through i) until said plurality of vias have been metalized.

21. A method of drilling and metalizing a plurality of deep vias as described in claim 20, wherein the step g) of removing said injection apparatus from drilled deep via is performed simultaneously with the step f) of injecting a conductive material into said deep via.

22. A method of drilling and metalizing a plurality of deep vias as described in claim 21, further comprising:
a) monitoring the conductive material being injected into said selected via until the level of conductive material reaches a selected conductive layer; and
b) terminating the injection of conductive material when the level of conductive material reaches a selected conductive layer.

23. A method of drilling and metalizing a plurality of deep vias as described in claim 20, wherein the step g) of removing said injection apparatus from drilled deep via is performed after the step f) of injecting a conductive material into said deep via.

24. A method of drilling and metalizing a plurality of deep vias as described in claim 23, further comprising:
a) monitoring the conductive material being injected into said selected via until the level of conductive material reaches a selected conductive layer; and
b) terminating the injection of conductive material when the level of conductive material reaches a selected conductive layer.
